(19) United States
(12) Patent Application Publication
(10) Pub. No.: US 2009/0009938 A1
(43) Pub. Date: Jan. 8, 2009

(54) Bag computer, front mount, top/bottom holder

(76) Inventor: Charles A. Daley, III, Rawai (TH)

Correspondence Address: Charles A. Daley III, P.O. Box 184, Karon P.O., T. Karon A. Muang, Phuket, 83100, TH

(21) Appl. No.: 12/074,115

(22) Filed: Mar. 3, 2008

Related U.S. Application Data
(60) Provisional application No. 60/958,265, filed on Jul. 5, 2007.

(51) Int. Cl. B65D 85/00; B65D 69/00; A45C 3/00; G06F 1/16; H05K 7/00

(52) U.S. Cl. 361/680; 206/320; 361/681

(57) ABSTRACT

Disclosed is a computer bag which mounts a matching computer on its outside front. The mount included a top and a bottom fixture with attachments which match the computer. The front of the mounted computer is left available for folding out a display so the computer can be viewed and used on the bag front. The bottom fixture attaches to the bottom of the computer and may pivot to make mounting easier. The top fixture includes a flap which allows the operator to shake the bag front flat as the computer is installed and the complimentary attachments on the flap are engaged. There may be an electrical connection leading from either of the outside mounting fixtures to the inside of the bag. A matching computer is described.

### CROSS-REFERENCE TO RELATED APPLICATIONS

This application claims the filing benefit under 35 U.S.C. §119(e) of U.S. Provisional Application No. 60/958,265, filed on Jul. 5, 2007, the entire teachings of which are incorporated herein by reference.
Related to patent application Ser. No. 11/799,011, filed May 1, 2007
Related to patent application Ser. No. 11/001,428, filed Nov. 30, 2004

### TECHNICAL FIELD

The present invention relates to a computer bag designed to mount computer equipment on its front for mobile use.

### BACKGROUND OF THE INVENTION

Bag computers are made to be used in mobile conditions while the computer is mounted to a bag front. It may be used while worn by the shoulder strap in front of the operator with his hands free for manipulating the computer or for other tasks. For example, a computer mounted on its matching bag may be used while standing in a line or sitting at a terminal waiting for a flight. Therefore, the front of the computer should be left unobstructed so it can be used and so a pivoting display can be folded out into the line of sight of the operator. A mounting structure consisting of two holders matching the top and bottom ends of the computer leaves the computer front free for use. The interior of the bag need not be accessed to use the computer and may be used to store normal cargo.

Some users may want to regularly dismount their computer from the bag front so it can be used on a desk. In this case, it may be better to mount the computer on the bag front instead of inside the bag. With the top and bottom holders, the computer may be mounted or dismounted in a few seconds without accessing the interior of the bag.

If the bag is full or contains awkwardly shaped objects, it may be difficult to attach the flat surface of the computer back to the front of the bag. Although a rigid panel may solve this problem, it adds weight to the bag. Instead, a mounting structure including a top flap allows the user to lift the flap and shake out bag front irregularities while mounting the computer. Additionally, the flap may include a rigid panel which may be used to pry the computer tightly to the bag front.

Although the bottom end of the computer may be held by a holster, a bottom holder with fittings complimentary to the computer may be fabricated and fitted to the bag front more easily, may hold the computer more securely, may be lighter and may more easily include an electrical connection.

Such a bag may include an electrical connection to the bag's interior. In this way, the user may carry batteries, memory or other peripherals inside the bag and already connected to the outside mounted computer.

Some bags similar to this one were described in application Ser. No. 11/001,428 and Ser. No. 11/799,011. This invention represents an improvement on them.

A computer suited to mount on some types of bags such as this was described in application Ser. No. 11/796,920. This invention represents an improvement on it.

### BRIEF DESCRIPTION OF THE INVENTION

The bag computer, front mount, top/bottom holder is a bag adapted to attach a special computer to the bag's front by using a bottom fixture matching complimentary fittings on the computer and a top fixture matching complimentary fittings on the computer. This arrangement allows the computer front to be unobstructed so a display can be pivoted outward and the computer used while mounted on the bag front. The computer can still be easily and quickly mounted and dismounted. A computer matching the bag may be provided.

The bottom fixture may be projections or receptacles which match the computer and hold it to the bag front. These may be attached to the bag front using a plate fixed to the bag front. There may also be an inside backing plate matching the outside plate. The bottom fixture may have an electrical connection which plugs into the computer. The inside backing plate may have plugs or wires to match other computer equipment or peripherals held inside the bag.

The top fixture is a flap with attachments which match complimentary fittings on the computer. The flap may be used to pull the bag front flat and remove bag bulge thus eliminating the need for a rigid panel in the bag front. Attachments, such as hooks, clips, snaps or footing and lever attach to the computer top edge or top front. There may be an electrical connection in the flap attachments.

The bag may include an inside mounting structures to hold additional computer equipments or peripherals and an outside cover flap.

### BRIEF DESCRIPTION OF THE SEVERAL VIEWS OF THE DRAWINGS

FIG. 1A shows the front computer mount with stab fitting attachments on the bottom computer holder and computer to match.

FIG. 1B shows the computer mounted in the top and bottom computer holders on the bag front.

FIG. 2A shows the front computer mount with a pivoting attachment on the bottom computer holder and computer to match.

FIG. 2B shows the computer mounted in the top and bottom computer holders on the bag front.

FIG. 3A shows the front computer mount with the top computer holder consisting of a flap with a rigid panel and projections for prying the attachment clips into place. A computer to match is shown.

FIG. 3B shows the computer mounted in the top and bottom computer holders on the bag front.

FIG. 4A shows the front computer mount with the top computer holder consisting of a flap with a rigid panel and projection attachment which may be pried into place. A computer to match is shown.

FIG. 4B shows a magnified view of the rigid panel and projection attachment on the flap end.

FIG. 4C shows a magnified view of computer's footing ridge.

FIG. 5A shows the front computer mount with the computer mounted. The top computer holder consisting of a flap with a rigid panel and projection attachment to match the computer's footing ridge.

FIG. 5B shows a magnified view of the rigid panel and projection attachment on the flap end while pried into place over the computer's footing ridge.

FIG. 6A Shows the computer made to mount on the bag front with the display stored.

FIG. 6B Shows the computer made to mount on the bag front with the pivoting display open.

### DETAILED DESCRIPTION OF THE INVENTION

The bag computer, front mount, top/bottom holder has a front back wall, an opposite back wall, two side walls, a top wall and a bottom wall. Each has an inside and outside surface. There may be a shoulder strap for carrying the bag. The top wall has access to the bag's interior and may have a closure, such as a zipper, to seal the opening. There may be a separate cover flap to cover, protect and conceal the mounted computer. The cover flap end permanently attached to the bag may be connected on the front wall, top wall or the top of the back wall. Openable attachments matching the bag may be found of the cover flap's distal edge to hold the flap in place. The flap may either fold back or fall down to expose the computer.

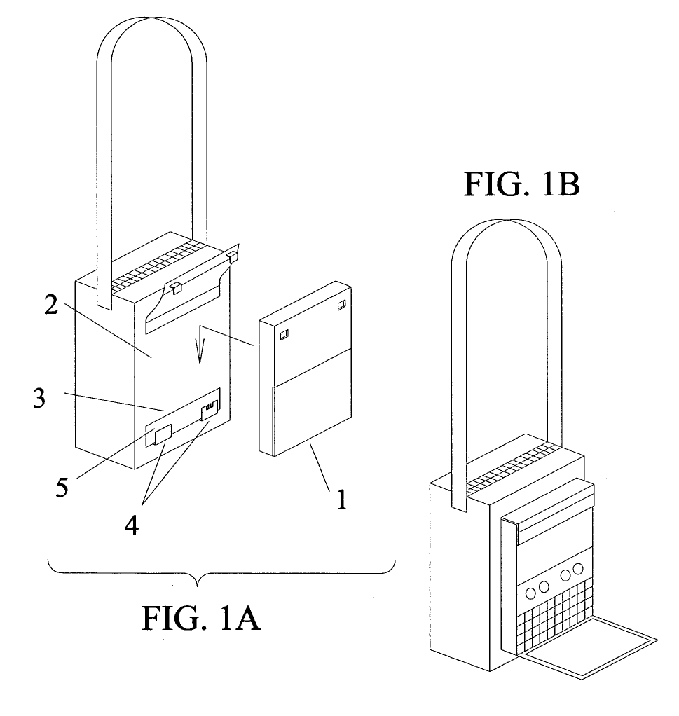

The bag computer, front mount, top/bottom holder, shown in FIG. 1A and FIG. 1B, mounts a computer 1 on the outside surface of the bag's front wall 2. There is a bottom computer holder 3 attached toward the lower part of the bag front. The mount has one or more attachments 4 matching attachments on the computer. The attachments may be hooks, bracket, sockets, pins, ledge, plug, blade or other attachments complimentary to the computer and removably holding the bottom of the computer to the bag's front wall. The computer engages to the attachment so that it cannot be pulled free of the bag under the outward pressure of bag bulge caused by cargo inside the bag. The bottom computer holder may be associated with or be part of a plate 5 attached to the front wall of the bag so to facilitate fixing the attachments to the bag and to prevent the attachments from twisting outward and disengaging. Instead, the bottom computer holder may be two separate pieces meant to fit and attach to the right and left lower corner areas of the computer.

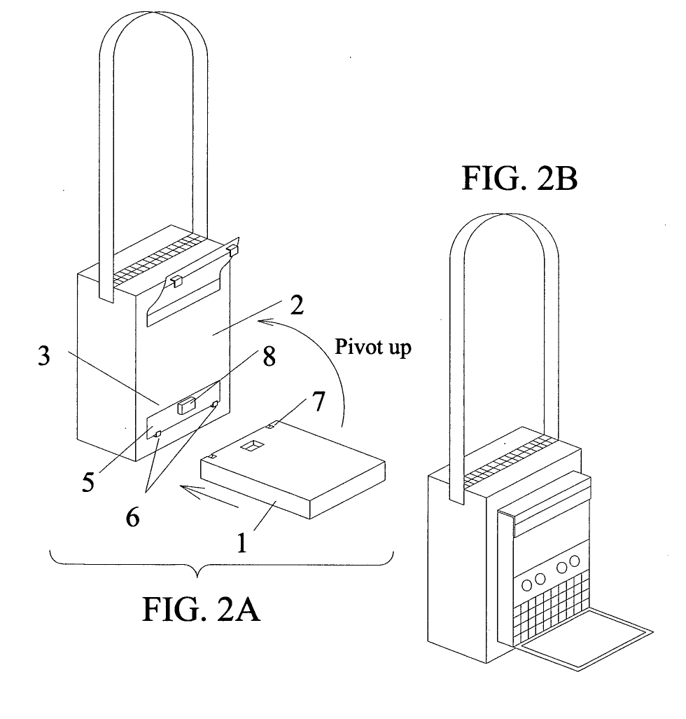

Alternatively, as shown in FIGS. 2A and 2B the bottom computer holder 3 may allow the computer to pivot from an approximately horizontal to a vertical position against the bag's front wall 2 during installation of the computer. Such a pivoting bottom computer holder may consist of a bottom mounting plate 5 about the width of the computer 1 to be mounted and attached to the lower part of the bag front and including on its outward facing surface one or more pivoting attachments 6 matching attachments 7 on the computer. The pivoting attachments may be hooks, half hinge axle or bearing, pivoting plate with attachments, ball and socket or other attachments complimentary to the computer and allowing it to pivot to a position flat against the bag's front wall while mounting. The mounting plate may have one or more pins or blocks 8 which engage when the computer is pivoted up and these help in resisting twisting of the computer.

Instead, the pivoting bottom computer holder may be a flexible fabric flap with attachments, such as hooks or snaps, on its surface.

The bottom computer holder may be riveted, screwed or permanently clipped to the bag front or through the bag front to a backing plate inside the bag.

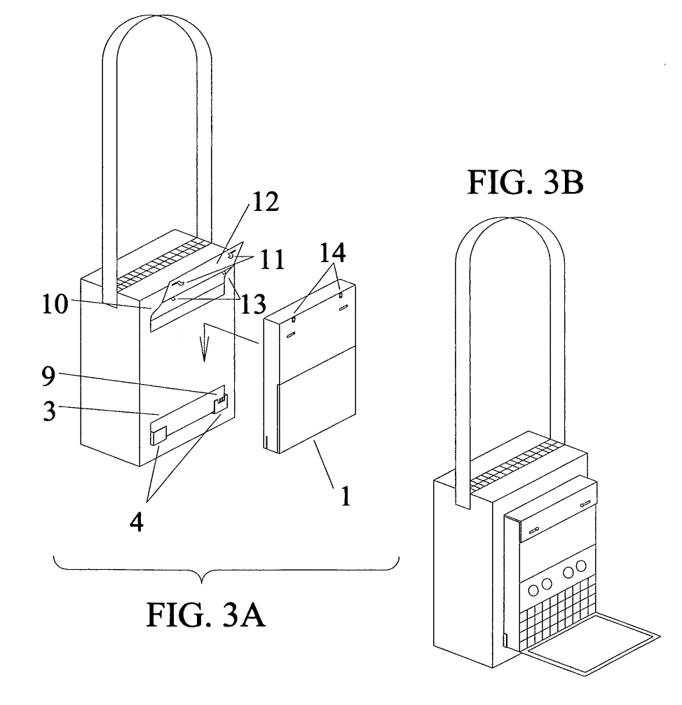

As shown in FIGS. 3A and 3B, the bottom computer holder 3 may have one or more electrical plugs 9 which engage when the computer is mounted to the bag's bottom computer holder attachment 4. The plug, which may include electrical wires, leads to the bag's interior where it may connect to other computer equipment such as batteries, memory, computer or other peripherals. A backing plate on the inside of the bag's front wall may have one or more plugs or plugs and wires coming from the outside plug and allowing connection between the outside computer and inside computer equipment. If a mounting plate with pivoting attachments is used, the one or more pins or blocks on the plate may have an electrical connection, such as a plug, which leads to the bag's interior.

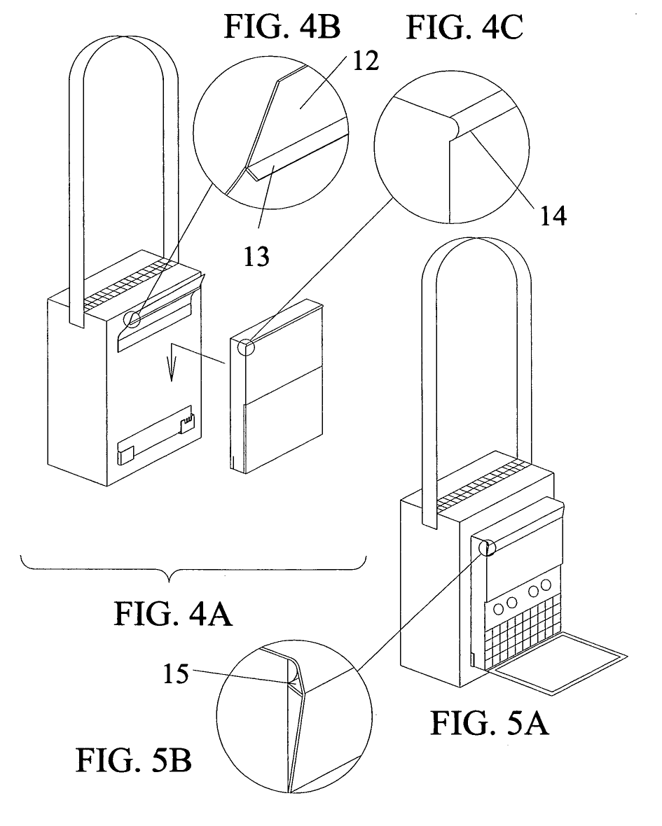

Higher up on the bag front is the top computer holder which consists of a flap 10 with distal attachment 11. The proximal end of the flap may be attached to or be an extension of the front or top walls. The flap is used to pull the bag front flat and fasten to the top edge or front of the computer where its complementary attachments are accessible. The attachments may be hooks, clips, snaps, magnets, rigid panel and projection, or other fasteners which are both easily opened and resistant to the outward pressure of bag bulge caused by cargo inside the bag. The flap may have elastic in it to help keep the bag front tight and help keep attachments engaged. Alternatively, the flap may have one or more rigid panels 12 in it or fastened to its distal edge to pry the bag front flat and engage the flap's attachments to the computer. A rigid panel may have one or more projections 13, such as pins, bar or ridge on its inboard edge to match a footing such as notches 14 or a ridge in the computer to assist in prying the panel into place. As shown in FIGS. 4A, 4B, 4C, 5A and 5B, if the bag flap's attachment is a rigid panel 12 and projection 13 to match a footing such as notches or ridge 14 on the computer, the rigid panel and projection may be levered into place 15 and form the entire attachment so that no further attachment may be needed on the flap.

The flap may have an electrical connection leading from the mounted computer to the bag interior. It may consist of a plug on the flap or flap attachments with wires leading through the flap, which may be double layered, through the bag's front wall and to the bag's interior.

The top computer holder may be riveted, screwed or otherwise bonded to the bag front or through the bag front to a backing plate inside the bag. The bag front may include reinforcement such as belting or additional material extending from the top to bottom computer holders.

The bag may have an inside computer equipment mounting structure, such as a footing and flap or docking port, attached to the inside surface of the bag's front wall. The mounting structure may be built in with or used in concert with the inside backing plate opposite the bottom computer holder. It may include a built-in electrical connection such as one or more plugs or plugs and wires coming from the outside plug and allowing connection between the outside computer and inside computer equipment.

The bag computer, front mount, top/bottom holder may include a computer to match the mounting structure on the outside of the bag's front wall.

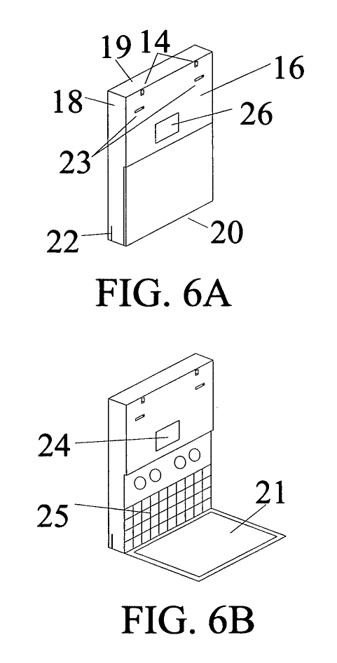

Shown in FIGS. 6A and 6B, the computer body has a front surface 16 facing outward when the computer is mounted on the bag, an opposite back surface, two side edges 18, a bottom edge 20 and a top edge 19. The computer may have a hinged display 21 which can be pivoted out into the line of sight of the operator when mounted on the bag front surface.

On or near the computer body's bottom edge there are one or more attachments or other fixtures 22 complimentary to the bag's bottom computer holder. The fixtures may go into the computer body or project out from it and may include notches, holes, slots, sockets, hooks, bars, pins or other fixtures complimentary to ones on the bag's bottom computer holder.

The attachment and/or fixtures may be capable of allowing the computer to pivot on the bag front as it is installed into the bottom computer holder. This may be done with hooks, half hinge axle or bearing, pivoting plate with attachments, ball and socket or other attachments on the computer and complimentary to the bag's bottom computer holder.

The computer body may be extended near the bottom edge to provide space near the bottom of the computer for the complimentary fixtures.

On the computer's top edge or front surface near the top edge there are one or more attachments or other fixtures 23, 14 complimentary to the distal flap attachments of the bag's top computer holder. The attachment may be or match hooks, clips, snaps, magnets or other attachments found on the flap. If the bag's flap attachment is a rigid panel and projection for footing such as notches 14 or ridge on the computer, the footing may form the entire attachments and no further attachments may be needed on the computer. The top edge of the computer body may be extended 24 to provide space on the front surface for the complimentary fixtures.

Near the corner between the front surface and top edge there may be one or more footings 14 for prying a rigid flap panel into place. These footings may be one or more holes, notches, troughs, ridges, projections or other fixture that can hold inboard edge of the bag's prying panel to the computer body while the opposite edge is pried into place. If the bag's flap attachment is a rigid panel and projection to match the computer's footing, the footing may form the entire attachment on the computer and no further attachments may be needed on the computer body.

On or near the bottom edge of the computer there may be an electrical plug to electrically connect the computer with the inside of the bag via a matching plug on the bag front. It may be part of the fixtures complimentary to the bag's bottom computer holder. The plug may be a separate fitting which engages when the computer is mounted to the bag front.

The electrical connection between the outside mounted computer and the interior of the bag may be found on the top computer holder. It may be part of the fixtures complimentary to the flap's attachments. The plug may be a separate fitting which engages when the computer is mounted to the bag front.

The computer may have a touchpad 26 on its front surface.

The computer may have a keyboard 25 adapted to use on a bag front. The keyboard may be 10 keys wide including the keys “a” to“;” on a standard QWERTY keyboard with standard size keys (approximately ¾ inch). Three or four rows may be included. Thumb keys substitute for essential keys farther to the right and left on the standard keyboard. The keyboard may include tactile guides such as troughs, ridges near the keys or keyboard edges to assure finger position and to help stabilize the keyboard with the hands/palms. The keyboard may be weatherproof.

I claim:

1. An apparatus for carrying computer equipment for mobile use comprising:
a. a bag having a front wall, an opposing back wall, two side walls, a bottom wall and a top wall including a top opening for providing access to the interior of the bag wherein each wall has an inside surface and an outside surface;
b. a bottom computer holder fixed to the lower outside front of the bag and including one or more attachments matching those on the computer to be carried;
c. a top computer holder fixed to the upper outside front of the bag consisting of a flap with one or more attachments matching those on the computer to be carried;

2. The apparatus of claim 1 wherein bottom computer holder allows the computer to pivot from an approximately horizontal to a vertical position against the bag front while being installed.

3. The apparatus of claim 1 further comprising an electrical connection on bottom computer holder and leading through the front wall to the bag's interior.

4. The apparatus of claim 1 further comprising an inside backing plate attached through the bag's front wall to the bottom computer holder and electrically connected to the bottom computer holder wherein the backing plate has one or more electrical plugs.

5. The apparatus of claim 1 further comprising one or more rigid panels in the top computer holder flap to assist in prying the computer to the bag front.

6. The apparatus of claim 5 further comprising one or more projections on the rigid panel's inboard edge to match a footing on the computer and assist in prying the panel into place.

7. The apparatus of claim 1 wherein the top computer holder attachment consists of a rigid panel with one or more projections on the rigid panel's inboard edge to match a footing on the computer and assist in prying and securing the panel into place.

8. The apparatus of claim 1 further comprising an electrical connection on top computer holder and leading through the front wall to the bag's interior.

9. The apparatus of claim 1 further comprising a computer equipment mounting structure fixed to the inside surface of the bag's front wall.

10. The apparatus of claim 1 further comprising:
a. a computer with a front surface facing away from the bag's front wall when mounted on the bag, an opposite back surface, two side edges, a top edge and a bottom edge;
b. one or more attachment fixtures on the top edge or front surface near the top edge matching the bag's top computer holder;
c. one or more attachment fixtures on or near the bottom edge matching the bag's bottom computer holder;
d. a display on the front surface.

11. The apparatus of claim 10 further comprising a keyboard with standard key size and QWERTY arrangement, 10 keys wide (A to ;) and thumb keys to actuate missing keys to the right and left.

12. The apparatus of claim 10 further comprising an electrical connection to the bag with a fitting matching one on the bag.

13. The apparatus of claim 10 wherein the display is pivotally attached to the computer's front surface along a horizontal axis so that it may be pivoted into the line of sight of the operator when mounted on the bag front.
